(19) United States
(12) Patent Application Publication
(10) Pub. No.: US 2026/0010068 A1
(43) Pub. Date: Jan. 8, 2026

(54) RETICLE CONTAINER WITH SENSOR DEVICE

(71) Applicant: GUDENG PRECISION INDUSTRIAL CO., LTD., NEW TAIPEI (TW)

(72) Inventors: Ming-Chien Chiu, NEW TAIPEI (TW); CHIA-HO CHUANG, NEW TAIPEI (TW); Chang-Da LIU, NEW TAIPEI (TW)

(21) Appl. No.: 19/257,720

(22) Filed: Jul. 2, 2025

Related U.S. Application Data
(60) Provisional application No. 63/667,876, filed on Jul. 5, 2024.

(51) Int. Cl. G03F 1/66

(52) U.S. Cl. CPC G03F 1/66

(57) ABSTRACT

A reticle container with a sensor device is provided. The reticle container includes an inner pod and an outer pod receiving the inner pod. The inner pod is provided with at least one sensor device. The sensor device continuously senses the state of the inner pod and outputs the sensed information.

### CROSS-REFERENCE TO RELATED APPLICATION

This application claims priority to and benefits of U.S. Provisional Application No. 63/667,876, filed Jul. 5, 2024, the content of which is incorporated by reference herein in its entirety.

### BACKGROUND OF THE INVENTION

### Field of the Invention

The present disclosure relates to reticle containers, and more particularly to a reticle container with a sensor device.

### Description of the Prior Art

The transfer of a reticle container during a semiconductor manufacturing process is subject to external influences, such as vibrations or tilting of equipment, and environmental conditions like temperature and humidity. Therefore, the reticle within the reticle container needs to be monitored in real-time during the transfer process. For instance, when the reticle container is a dual pod and is transferred within a scanner of an exposure apparatus, its inner pod separates from its outer pod, and a robotic arm grips the inner pod to perform the transfer operation. At this point in time, if the state of the inner pod in the equipment is abnormal, it is difficult to promptly identify the exact location and cause of the issue, which hinders the improvement of subsequent manufacturing yield. In particular, conventional inner pods are flat metal containers manufactured by CNC machining, with rather limited spatial utilization and functional integration. Therefore, a pressing issue in the field is how to provide an inner pod with a sensor device under the condition of limited structural capacity.

### SUMMARY OF THE INVENTION

In view of the aforesaid drawbacks of the prior art, the present disclosure provides a reticle container with a sensor device, applicable to a dual pod having an inner pod and an outer pod. The sensor device is disposed in the inner pod to continuously sense and record the operating state (for example, tilt angle and vibration) and environmental changes (for example, temperature and humidity) of the inner pod. The sensed information can be output in real time or record and then output to a monitoring device (for example, back-end system) under specific situations, thereby enabling quick identification of the positions and causes of abnormal vibrations and tilts occurring inside a machine. Furthermore, the operating state and environmental changes of the inner pod are continuously recorded while the reticle container is being transferred between factories, so as to monitor whether the reticle is transferred under optimal conditions.

The disclosure provides a reticle container, comprising an inner pod and an outer pod receiving the inner pod, wherein the inner pod comprises: a base and a lid; and at least one sensor device disposed at the base and/or the lid and configured to continuously sense internal environmental states, external environmental states or operating states of the inner pod, wherein, when the sensor device is disposed at the base, at least one receiving recess is disposed on an inner side or outer side of the base and configured to receive the sensor device.

In a specific embodiment, the at least one receiving recess is centrally located at the base.

In a specific embodiment, when a plurality of receiving recesses is provided, the plurality of receiving recesses is spaced apart with a central region of the base, and has therein identical sensor devices or non-identical sensor devices.

In a specific embodiment, the sensor device is a vibration sensor device, parallelism sensor device, temperature sensor device, humidity sensor device, or any combination thereof.

In a specific embodiment, after the sensor devices have been received in the plurality of receiving recesses, a center of mass is established, allowing an offset to exist between a geometric center of the base and the center of mass of the base, with the offset range being less than or equal to 4 mm.

In a specific embodiment, the base has a sealing plate configured to correspond to the receiving recesses so as to cover and hermetically seal the sensor device, allowing an outer surface of the sealing plate to be coplanar with an upper surface or lower surface of the base.

In a specific embodiment, a step is disposed between the receiving recess and the upper surface or the lower surface of the base and has a resting surface and a supporting surface, and a depth between the supporting surface and the upper surface or the lower surface of the base is greater than a depth between the resting surface and the upper surface or the lower surface of the base, with the sealing plate disposed on the resting surface, and with the sensor device disposed on the supporting surface.

In a specific embodiment, the sealing plate is made of a material that does not shield electronic signals.

In a specific embodiment, the at least one sensor device is disposed on the inner side of the base, and an end of the at least one sensor device faces the base.

In a specific embodiment, signals sensed by the at least one sensor device are transmitted to a back-end system.

In a specific embodiment, the outer pod and the inner pod both have a non-square rectangular shape with a long side and a short side, and the inner pod is configured to receive a non-square rectangular reticle.

### BRIEF DESCRIPTION OF THE DRAWINGS

The disclosure is depicted by drawings, illustrated by non-restrictive, non-exhaustive embodiments, and described below. The drawings are not drawn to scale but are aimed at disclosing the structural features and principles of the disclosure.

FIG. 1A is an exploded view of a reticle container according to the first embodiment of the disclosure.

FIG. 1B is a perspective view of the reticle container assembled according to the first embodiment of the disclosure.

FIG. 1C is a cross-sectional view of the reticle container taken along line A-A of FIG. 1B.

FIG. 2 is an exploded view of a variant 1 of the first embodiment.

FIG. 3 is an exploded view of a variant 2 of the first embodiment.

FIG. 4A shows the configuration of the bottom of a base according to the second embodiment of the disclosure.

FIG. 4B is a cross-sectional view of the base taken along Y axis of FIG. 4A.

FIG. 5 shows the configuration of the bottom of the base according to a variant 1 of the second embodiment of the disclosure.

FIG. 6A shows the configuration of the inner side of a lid of the reticle container according to the third embodiment of the disclosure.

FIG. 6B is a cross-sectional view of the reticle container according to the third embodiment of the disclosure.

FIG. 7 shows the configuration of the inner side of the lid according to a variant 1 of the third embodiment of the disclosure.

FIG. 8 is a block diagram of a sensor device of the disclosure.

### DETAILED DESCRIPTION OF THE EMBODIMENTS

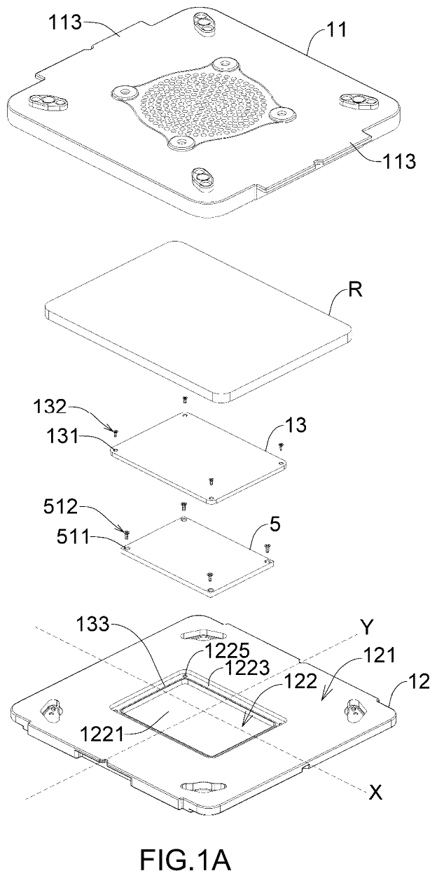

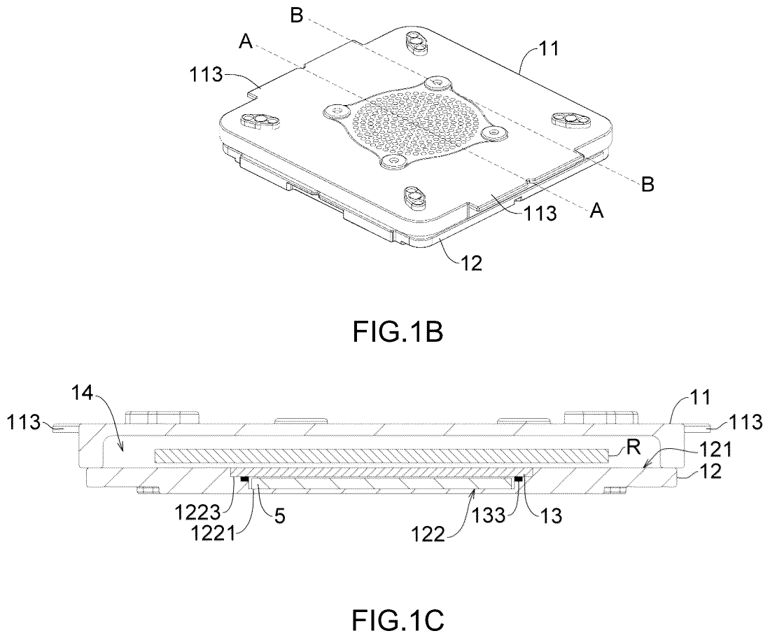

FIG. 1A is an exploded view of a reticle container according to the first embodiment of the disclosure. The disclosure provides a reticle container with a sensor device, adapted to a dual pod comprising an inner pod and an outer pod, especially the inner pod. To clearly present the inventive content, the outer pod is omitted from the drawings of the disclosure. The inner pod comprises a lid 11, base 12, and sensor device 5. The lid 11 has a handle 113 disposed on each of two sides and configured to enable robotic arm handling, and a filtering component configured to filter the gas entering the inner pod from the outer pod. The base 12 provides the sensor device 5. As shown in FIGS. 1B and 1C, the lid 11 and the base 12 are engaged together to form a receiving space 14 for receiving a reticle R therein.

According to the disclosure, the reticle container comprises at least one sensor device 5 disposed at the base 12 and/or the lid 11 of the inner pod and configured to continuously sense internal and external environmental states of the inner pod. When disposed at the base 12, the sensor device 5 is positioned on the inner side of the base 12 (i.e., on the side where the reticle R is stored) and/or on the outer side of the base 12 (i.e., on the side where the reticle R is not stored). At least one receiving recess 122 is disposed on the inner side and/or outer side of the base 12, allowing the sensor device 5 to be disposed in the receiving recess 122. When the sensor device 5 is disposed at the lid 11, the sensor device 5 can be positioned on the inner side and/or outer side of the lid 11. Signals sensed by the sensor device 5 are transmitted to a back-end system for receiving information about the inner pod, such as internal environmental states, external environmental states or operating state of the inner pod, allowing the user to continuously monitor the state of the inner pod through the back-end system.

In the first embodiment of the disclosure, the base 12 has an upper surface 121 opposing the lid 11 and has one or a plurality of receiving recesses 122 extending downward from the upper surface 121 for receiving the sensor device 5, which is configured to continuously sense the operating state and environmental state of the inner pod. In this embodiment, the receiving recess 122 is located within a central region of the base 12 and is a shallow space defined by a length, a width, and a depth. The sensor device 5 is a flat integration device, such as IC package. Preferably, the sensor device 5 is formed by integrating multiple sensors and may include, but is not limited to, one or a combination of a temperature sensor, humidity sensor, vibration sensor, tilt sensor, and position sensor. The sensor device 5 is secured in the receiving recess 122 using adhesive and/or

screws. The adhesive is a low-VOC material to avoid affecting the surrounding environment. In this embodiment, the sensor device 5 has a mounting hole 511 configured to receive a fasten member 512 to fix the sensor device 5 in place inside the receiving recess 122, thereby preventing displacement of the sensor device 5 due to movement of the base 12. Optionally, a high-purity encapsulant is used to cover the sensor device 5 to prevent gas release and protect the sensor device 5 to ensure its proper operation in a vacuum environment.

The base 12 further comprises a sealing plate 13 attached to a flange or an annular step between the receiving recess 122 and the upper surface 121 to cover the sensor device 5. The outer surface of the sealing plate 13 is coplanar with the upper surface 121 of the base 12 to maintain a flat profile of the base 12. The term “coplanar” specifies that the two surfaces substantially flush with each other to prevent the outer surface of the sealing plate 13 attached to the base 12 from interfering with the lower surface of the reticle R. Optionally, the sealing plate 13 has a mounting hole 131 configured to receive a fastening member 132 to fix the sealing plate 13 to the base 12. This helps prevent interference between the sensor device 5 and the reticle R, or avoids affecting the appearance of the base 12. Preferably, the sealing plate 13 is made of a material that does not shield electronic signals, such as quartz, plastic, or other non-conductive materials.

As shown in FIG. 1A, an X-axis is defined as a straight line passing through the center points of one pair of opposing sides of the base 12, and a Y-axis is defined as a straight line passing through the center points of the other pair of opposing sides of the base 12. The receiving recess 122 is substantially located within a central region of the base 12, i.e., at the intersection of the X-axis and Y-axis. Preferably, the shapes of the receiving recess 122 and/or the sensor device 5 are symmetric about the X-axis or Y-axis. Consequently, after the sensor device 5 has been received in the base 12, the overall center of mass of the inner pod remains substantially the same as its geometric center—in other words, even with the sensor device 5 installed, the overall center of mass of the inner pod still located substantially at the intersection of the X-axis and Y-axis. Preferably, an offset exists between the center of mass of the base 12 and the geometric center of the base 12, and the offset range is less than or equal to 4 mm to prevent dropping or overturning when the base 12 is moved by a robotic arm. The center of mass and the offset are simulated and calculated using design software or measurement jigs based on the material properties and assembly configuration of the components. Since methods of the such calculation methods are not the technical focus of the disclosure, they are omitted for the sake of brevity.

The position of the sensor device 5 and the position of the receiving recess 122 are properly chosen according to the actual weights of the base 12 and the sensor device 5, so that the center of mass of the base 12 provided with the sensor device 5 substantially coincides with the geometric center of the base 12. The above configuration is not limited to the arrangement show in this embodiment. In an embodiment, the center of mass is preferably located at or near the intersection of the X-axis and Y-axis, when both the outer pod and the inner pod have a non-square rectangular shape with a long side and a short side, and the inner pod is configured to receive a non-square rectangular reticle with a 6×12 inch non-square rectangular shape. Optionally, a sealing structure 133, such as a rubber gasket, is disposed between the sealing plate 13 and the receiving recess 122 to maintain an airtight environment within the receiving recess 122 and prevent gas from intruding into the receiving recess 122.

Referring to FIG. 1C, there is shown a cross-sectional view of the reticle container taken along line A-A of FIG. 1B when the lid 11 engages with the base 12. Steps are formed around the periphery of the receiving recess 122, allowing the sensor device 5 to be received within the receiving recess 122 and enabling the sealing plate 13 to be attached to the steps, thereby cover the sensor device 5 without applying pressure thereto. Specifically, the steps each have a resting surface 1223, a sensor device supporting surface 1221 is formed at the bottom of the receiving recess 122, and the sensor device 5 is placed on the sensor device supporting surface 1221. In this embodiment, the receiving recess 122 is rectangular in shape, and the continuous resting surface 1223 is present along four sides of the receiving recess 122, allowing the sealing plate 13 to correspond in shape to the receiving recess 122 and rest on the resting surface 1223. As shown in FIG. 1A, the resting surface 1223 has a plurality of fastening holes 1225 corresponding in position to the mounting hole 131 of the sealing plate 13 to be fixed in place via the fastening member 132. In this embodiment, the sensor device 5 is disposed in the inner pod and positioned below the reticle R. Therefore, the sensor device 5 can continuously senses the environmental state in the inner pod, and accurately senses the operating state of the reticle R during the transfer process.

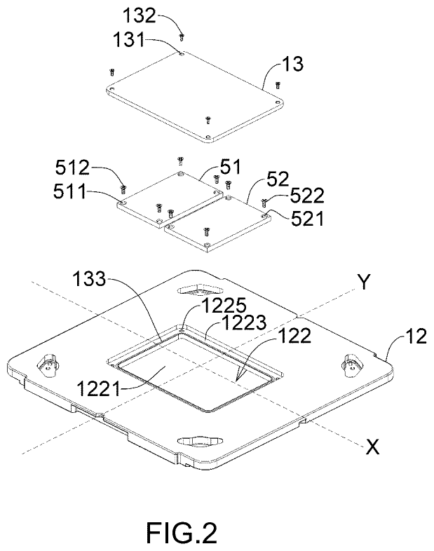

A variant of this embodiment is illustrated by FIG. 2 and distinguished by the receiving recess 122 having therein the two sensor devices 51, 52. The two sensor devices 51, 52 are either identical or non-identical. Each of the two sensor devices 51, 52 is a temperature sensor, humidity sensor, vibration sensor, tilt sensor, position sensor, or any combination thereof. The two sensor devices 51, 52 are arranged side by side in the receiving recess 122 and configured to continuously sense the operating state and environmental state of the inner pod. The two sensor devices 51, 52 are secured in the receiving recess 122 using adhesive and/or screws. The adhesive is a low-VOC material to avoid affecting the surrounding environment. In this embodiment, the two sensor devices 51, 52 have the mounting holes 511, 521 configured to engage with the fastening members 512, 522 to allow the two sensor devices 51, 52 to be fixed in place inside the receiving recess 122 and thus prevented from undergoing unanticipated displacement. In another possible variant embodiment, the two sensor devices 51, 52 are arranged to become a lower sensor device and an upper sensor device.

An X-axis is defined as a straight line passing through the center points of one pair of opposing sides of the base 12, and a Y-axis is defined as a straight line passing through the center points of the other pair of opposing sides of the base 12. The receiving recess 122 is substantially located within a central region of the base 12, i.e., at or near the intersection of the X-axis and Y-axis, and the shapes of the two sensor devices 51, 52 are symmetric about the Y-axis. The positions of the two sensor devices 51, 52 and the position of the receiving recess 122 are appropriately determined according to the actual weights of the base 12 and the two sensor devices 51, 52, so that the center of mass of the base 12 provided with the two sensor devices 51, 52 substantially coincides with the geometric center of the base 12. The above configuration is not limited to the arrangement shown in this embodiment.

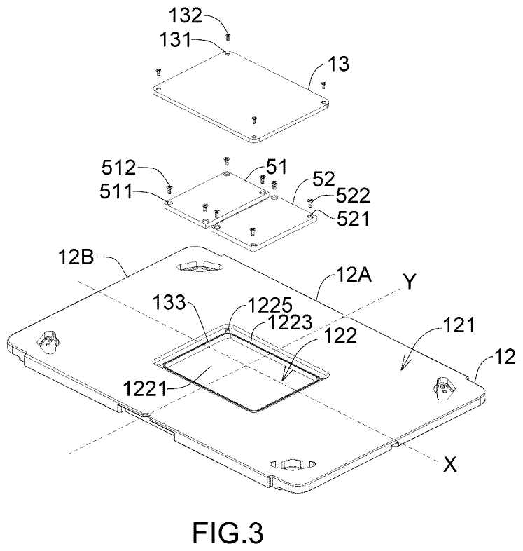

The disclosure is applied to containers for use with non-square rectangular reticles. FIG. 3 illustrates another variant of this embodiment, with the difference being that the inner pod has a pair of long sides and a pair of short sides. The inner pod receives a non-square rectangular reticle, such as a 6×12 inch reticle (not shown), and the outer pod receiving the inner pod is also a non-square rectangular pod with a pair of long sides and a pair of short sides. Specifically, the base 12 has non-square long sides 12A and short sides 12B, and has the receiving recess 122 for receiving at least one sensor device 51, 52 configured to continuously sense the moving state and environmental state of the inner pod. The sensor devices 51, 52 are secured in the receiving recess 122 using adhesive and/or screws. The adhesive is a low-VOC material to avoid affecting the surrounding environment. In this embodiment, the two sensor devices 51, 52 have the mounting holes 511, 521 configured to receive the fastening members 512, 522 to allow the two sensor devices 51, 52 to be fixed in place inside the receiving recess 122 and thus prevented from undergoing unanticipated displacement.

An X-axis passes through the center points of the two short sides 12B of the base 12, and a Y-axis passes through the center points of the two long sides 12A of the base 12. The receiving recess 122 is substantially centrally located at the base 12, i.e., at the intersection of X-axis and Y-axis, and the two sensor devices 51, 52 are symmetric about the Y-axis. The positions of the two sensor devices 51, 52 and the position of the receiving recess 122 are appropriately determined according to the actual weights of the base 12 and the two sensor devices 51, 52, so that the center of mass of the base 12 provided with the two sensor devices 51, 52 substantially coincides with the geometric center of the base 12. The above configuration is not limited to the arrangement shown in this embodiment.

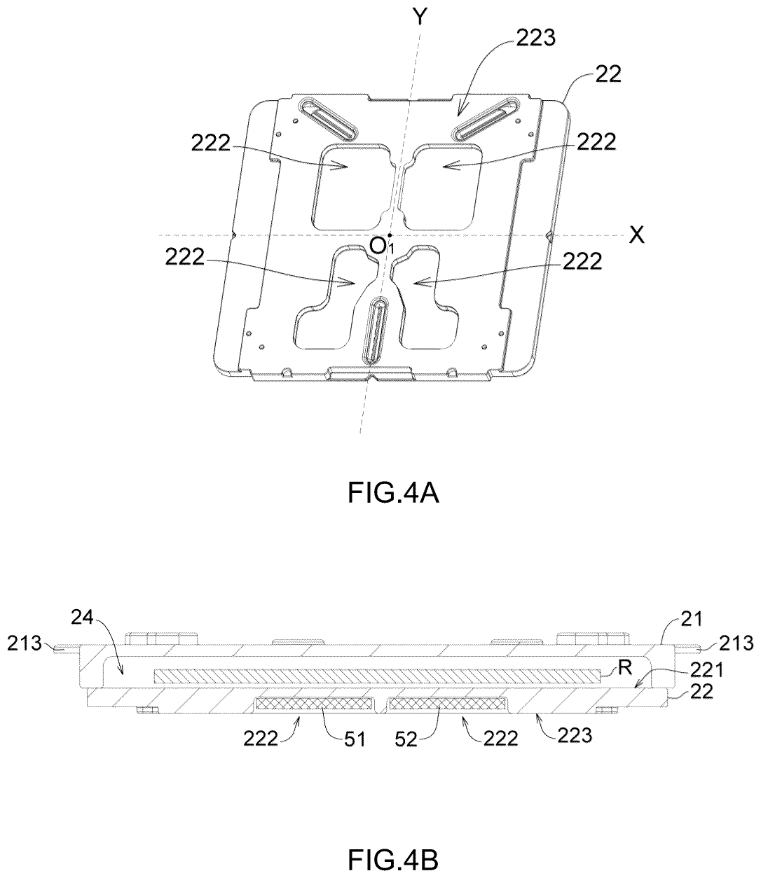

FIG. 4A shows the configuration of the bottom of a base 22 of a reticle container according to the second embodiment of the disclosure. The second embodiment differs from the first embodiment in that the base 22 has a different receiving recess design, and the sensor devices 51, 52 are disposed outside the base 22 to reduce interference between the reticle R and the sensor devices 51, 52.

FIG. 4B is a cross-sectional view of the base 22 taken along line A-A of FIG. 1B when the lid 21 engages with the base 22 in the second embodiment. The base 22 has an upper surface 221 and a lower surface 223 opposing the upper surface 221. In this embodiment, the receiving recesses are formed from the lower surface 223 as illustrated. The lower surface 223 of the base 22 extends upward to form one or a plurality of receiving recesses 222 configured to receive the sensor devices 51, 52. The receiving recesses 222 are shallow spaces, each having a depth sufficient to prevent the sensor devices 51, 52 from protruding beyond the lower surface 223 of the base 22. The plurality of receiving recesses 222 is spaced apart within a central region of the base 22. The plurality of sensor devices 51, 52 is either identical or non-identical and is received in the receiving recesses 222 respectively; alternatively, each of the receiving recesses 222 receives the multiple sensor devices 51, 52. Preferably, the plurality of sensor devices 51, 52 are communicatively connected. The sensor devices 51, 52 are secured in the receiving recesses 222 using adhesive and/or screws, with the adhesive being a low-VOC material. Alternatively, as in the first embodiment, the sensor devices 51, 52 are secured in the receiving recesses 222 using the fastening members. Optionally, this embodiment may include the sealing plates 13 (not shown) as shown in the first embodiment and configured to respectively cover and hermetically seal the sensor device 5, allowing an outer surface of the sealing plates 13 to be coplanar with the lower surface 223 of the base 22.

An X-axis passes through the centers of a pair of opposing sides of the base 22, and a Y-axis passes through the centers of the other pair of opposing sides of the base 22. A center position O1 located at the intersection of the X-axis and Y-axis coincides with the geometric center of the base 22. One or a plurality of sensor devices 51, 52 are symmetric about the Y-axis. The position of one or the plurality of sensor devices 51, 52 and the positions of the receiving recesses 222 are appropriately determined according to the actual weights of the base 22 and the two sensor devices 51, 52, so that the center of mass of the inner pod provided with the sensor devices 51, 52 substantially coincides with the geometric center of the base 22. The above configuration is not limited to the arrangement in this embodiment. In this embodiment, the center of mass of the base 22 provided with the two sensor devices 51, 52 substantially coincides with the geometric center of the base 22. Preferably, an offset exists between the center of mass of the base 22 provided with the sensor devices 51, 52 and the geometric center of the base 22, and the offset range is less than 4 mm. In this way, when the reticle container is transferred by a robotic arm, the risk of dropping due to center of mass deviation during the transfer process can be avoided, thereby preventing damage. In this embodiment, the base 22 has four sensor devices respectively placed in the four quadrants defined by the X-axis and Y-axis and are symmetric about the Y-axis. Since the receiving recesses 222 are formed from the lower surface 223, they are designed with different shapes to avoid interference with the original three KC grooves while ensuring that the center of mass of the base 22 provided with the sensor device 5 to substantially coincide with the geometric center of the base 22.

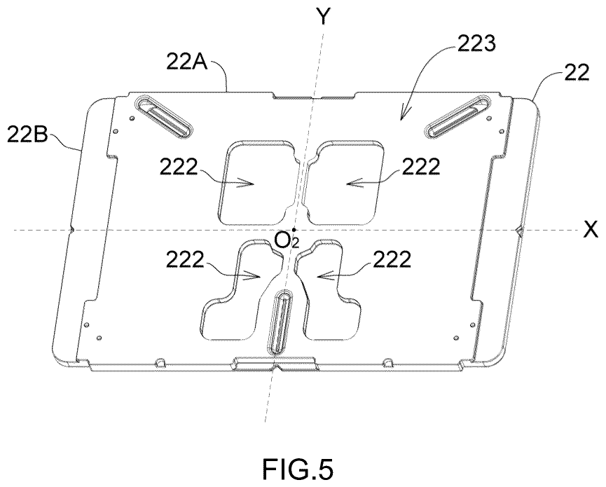

FIG. 5 shows a variant of this embodiment, differing in that the inner pod has a pair of long sides and a pair of short sides. Specifically, the base 22 has non-square long sides 22A and short sides 22B. In this embodiment, an X-axis passes through the centers of the two short sides 22B of the base 22, and a Y-axis passes through the centers of the two long sides 22A of the base 22. The X-axis and Y-axis define four quadrants configured to accommodate four sensor devices respectively. The four sensor devices are symmetric about the Y-axis. An central position O2 located at the intersection of the X-axis and Y-axis coincides with the geometric center of the base 22. In this embodiment, the center of mass of the base 22 provided with the sensor devices 51, 52 substantially coincides with the geometric center of the base 22. Preferably, the distance between the center of mass of the base 22 provided with the sensor devices 51, 52 and the geometric center of the base 22 is less than 4 mm.

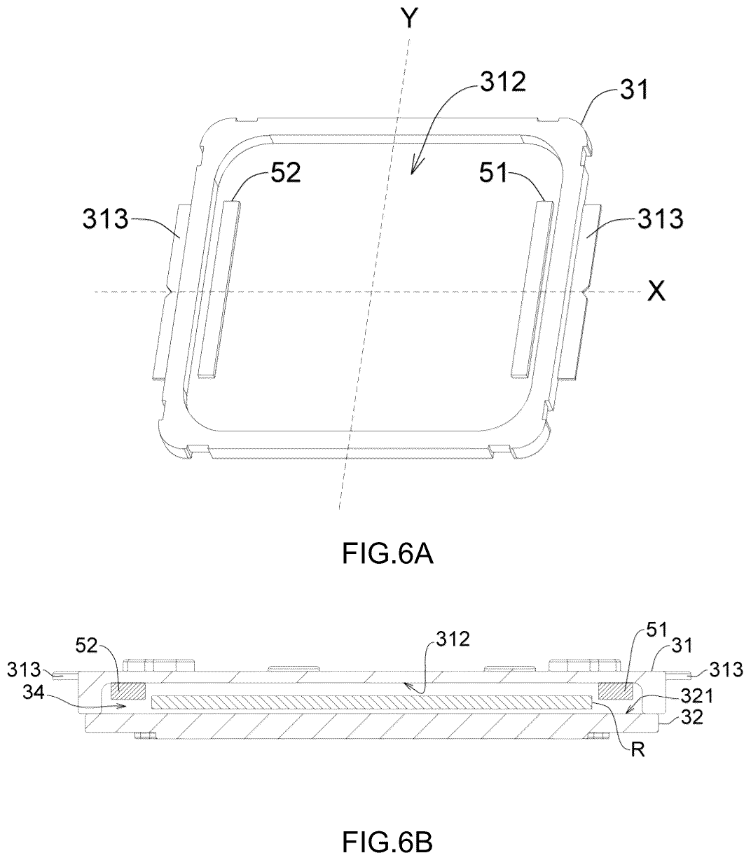

FIG. 6A shows the configuration of the inner side of a lid 31 of the reticle container according to the third embodiment. In this embodiment, the reticle container comprises an inner pod and an outer pod (not shown) receiving the inner pod, wherein the lid 31 of the inner pod is provided with the sensor devices 51, 52.

FIG. 6B is a cross-sectional view of the reticle container according to the third embodiment of the disclosure. The inner pod comprises a base 32 and a lid 31. A handle 313 is disposed on each of two sides of the upper edge of the lid 31. When the base 32 and the lid 31 are engaged with each other, an upper surface 321 of the base 32 and a lower surface 312 of the lid 31 jointly define a receiving space configured to receive the reticle R, and the sensor devices 51, 52 are disposed on the inner side of the lid 31, such as on the lower surface 312, of the lid 31. In this embodiment, the sensor devices 51, 52 are received in the receiving space and avoid the reticle R and other structures in a receiving space 34. The sensor devices 51, 52 are fixed to the lid 31 using adhesive and/or screws. The adhesive is a low-VOC material to avoid affecting the surrounding environment.

Specifically, the lid 31 has sidewalls extending downward from the top portion, and the sensor devices 51, 52 can be disposed adjacent to the sidewalls so as to avoid the reticle R. Referring to FIG. 6A, an X-axis passes through the centers of a pair of opposing sides of the lid 31, and a Y-axis passes through the centers of the other pair of opposing sides of the lid 31, and the shapes or positions of the two sensor devices 51, 52 are symmetric about the X-axis or Y-axis. In this embodiment, the two sensor devices 51, 52 each have an elongated body, are positioned near two opposing sides of the sidewalls respectively, and are symmetric about the Y-axis, allowing the shapes of the two sensor devices 51, 52 to be symmetric about the X-axis respectively. The positions of the two sensor devices 51, 52 can be appropriately determined according to their weights, so that the center of mass of the lid 31 provided with the sensor devices 51, 52 substantially coincides with the geometric center of the lid 31 to prevent overturning and damage during robotic arm handling due to center of mass deviation. Therefore, the sensor devices can be directly disposed in the inner pod without modifying the existing structure to reduce manufacturing costs, continuously sense the environment in the inner pod, and thereby monitor the environmental state of a reticle stored in the inner pod.

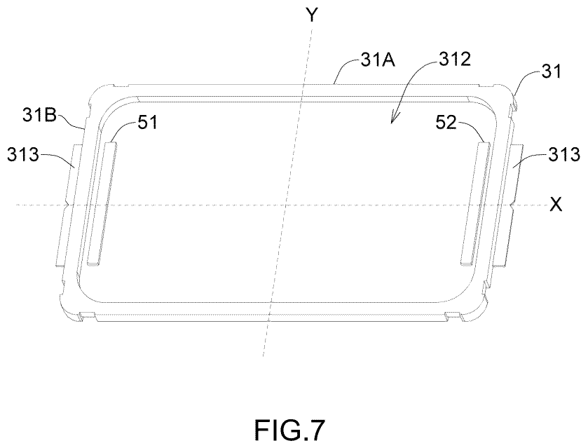

FIG. 7 shows a variant of this embodiment, differing in that the inner pod having a pair of long sides and a pair of short sides. Specifically, the lid 31 has non-square long sides 31A and short sides 31B. In this embodiment, an X-axis passes through the centers of the two short sides 31B of the lid 31, and a Y-axis passes through the centers of the two long sides 31A of the lid 31. The two sensor devices 51, 52 are symmetric about the Y-axis and are arranged along the short sides 31B. The positions of the two sensor devices 51, 52 are appropriately determined according to their weights, so that the center of mass of the lid 31 provided with the two sensor devices 51, 52 substantially coincides with the geometric center of the lid 31, allowing the intersection of the X-axis and Y-axis. This arrangement is not limited to the configuration shown in this embodiment.

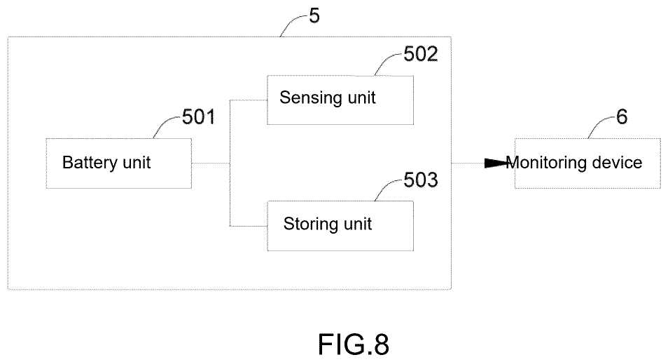

FIG. 8 is a block diagram of a sensor device of the disclosure. The sensor device 5 comprises one or more sensing units 502 configured to continuously sense internal environmental states, external environmental states or operating state of the inner pod. Depending on objectives of sensing, the sensing units 502 can be configured to sense tilt angles, accelerations, displacements, and vibrations and/or sense the internal and external environments of the inner pod, such as temperature, humidity, and pressure. To be specific, the sensing units 502 are vibration sensors or tilt sensors. Alternatively, the sensing units 502 are temperature sensors, humidity sensors, or pressure sensors.

Signals from the reticle container are connected to a back-end system, and information sensed by the sensor device 5 is transmitted to the back-end system, allowing users to continuously monitor the state of the reticle container. In an embodiment, the sensor device 5 can be switched between a real-time sensing mode and an offline sensing mode. In the real-time sensing mode, the sensed information about the operating state or environmental state of the inner pod is continuously outputted to a monitoring device 6 via wired or wireless connections, the cause and location can be immediately identified. When the inner pod is exposed to a strong magnetic field (such as within the machine) where signal interference prevents real-time output to the monitoring device 6, the sensor device 5 is switched to the offline sensing mode automatically or under user control. Thus, the sensor device 5 records information sensed by the sensing unit 502 to a storing unit 503. When the inner pod arrives at a location free from signal interference, it outputs the recorded information, allowing information from the location where real-time monitoring is not possible to still be obtained. The sensor device 5 further comprises a battery unit 501 configured to store and supply electric power and configured to be charged via wired or wireless connections.

It should be understood that specific embodiments of the disclosure can be freely combined. The specific embodiments of the disclosure merely serve illustrative purposes. The specific embodiments of the disclosure are subject to various changes without departing from the spirit and scope of the claims of the disclosure and still fall within the scope of the claims of the disclosure. Therefore, the specific embodiments of the disclosure are not restrictive of the disclosure. The real spirit and scope of the disclosure should be defined by the appended claims.

What is claimed is:

1. A reticle container, comprising an inner pod and an outer pod receiving the inner pod, the inner pod comprising:
a base and a lid; and
at least one sensor device disposed at the base and/or the lid and configured to continuously sense internal environmental states, external environmental states, or operating states of the inner pod,
wherein, when the sensor device is disposed at the base, at least one receiving recess is disposed on an inner side or outer side of the base and configured to receive the sensor device.

2. The reticle container of claim 1, wherein the at least one receiving recess is centrally located at the base.

3. The reticle container of claim 1, wherein, when a plurality of receiving recesses is provided, the plurality of receiving recesses is spaced apart within a central region of the base, and has therein identical sensor devices or non-identical sensor devices.

4. The reticle container of claim 1, wherein the sensor device is a vibration sensor device, parallelism sensor device, temperature sensor device, humidity sensor device, or any combination thereof.

5. The reticle container of claim 3, wherein, after the sensor devices have been received in the plurality of receiving recesses, a center of mass is established, allowing an offset to exist between a geometric center of the base and the center of mass of the base, with the offset range being less than or equal to 4 mm.

6. The reticle container of claim 1, wherein the base has a sealing plate configured to correspond to the receiving recess so as to cover and hermetically seal the sensor device, allowing an outer surface of the sealing plate to be coplanar with an upper surface or lower surface of the base.

7. The reticle container of claim 6, wherein a step is disposed between the receiving recess and the upper surface or the lower surface of the base and has a resting surface and a supporting surface, and a depth between the supporting surface and the upper surface or the lower surface of the base is greater than a depth between the resting surface and the upper surface or the lower surface of the base, with the sealing plate disposed on the resting surface, and with the sensor device disposed on the supporting surface.

8. The reticle container of claim 6, wherein the sealing plate is made of a material that does not shield electronic signals.

9. The reticle container of claim 1, wherein the at least one sensor device is disposed on the inner side of the base, and one side of the at least one sensor device faces toward the base.

10. The reticle container of claim 1, wherein signals sensed by the at least one sensor device are transmitted to a back-end system.

11. The reticle container of claim 1, wherein the outer pod and the inner pod both have a non-square rectangular shape with a long side and a short side, and the inner pod is configured to receive a non-square rectangular reticle.
